(19) United States
(12) Patent Application Publication
(10) Pub. No.: US 2006/0250129 A1
(43) Pub. Date: Nov. 9, 2006

(54) Method of measuring sub-micrometer hysteresis loops of magnetic films

(75) Inventors: Te-Ho Wu, Douliou City (TW); Lin-Hsiu Ye, Douliou City (TW); Jia-Mou Lee, Douliou City (TW)

Correspondence Address: SUGHRUE MION, PLLC, 2100 PENNSYLVANIA AVENUE, N.W., SUITE 800, WASHINGTON, DC, 20037, US

(73) Assignee: National Yunlin University of Science and Technology

(21) Appl. No.: 11/397,608

(22) Filed: Apr. 5, 2006

(30) Foreign Application Priority Data
Apr. 7, 2005 (TW) 94111074

(51) Int. Cl. G01R 33/12; G01N 27/72

(52) U.S. Cl. 324/228

(57) ABSTRACT

A method of measuring sub-micrometer hysteresis loops of a magnetic film is provided. First, a magnetic field is applied to a sample of a magnetic film, and a polarization microscope is used to observe an analytical area of the sample. Next, the observed dynamic video is converted to many digital pictures stored in chronological order. Then, the grayscale values of each selected pixel are read and converted to the corresponding relative magnetic moments, and hysteresis loops of each selected pixel are drawn.

### RELATED APPLICATIONS

The present application is based on, and claims priority from, Taiwan Application Serial Number 94111074, filed Apr. 7, 2005, the disclosure of which is hereby incorporated by reference herein in its entirety.

### BACKGROUND

1. Field of Invention

The present invention relates to a method of measuring hysteresis loops of a ferromagnetic material. More particularly, the present invention relates to a method of measuring sub-micrometer hysteresis loops of a perpendicular anisotropic magnetic film.

2. Description of Related Art

Because local chemical and structural defects formed in magnetic films during magnetic film formation, the magnetic and magnitude distribution on the magnetic films is not uniform. A uniform magnetic distribution in magnetic films becomes very important when the magnetic films are applied to film recording and used as a memory material. For example, the coercivity distribution on a magnetic film affects the difficulty of data writing and erasing on the magnetic film, and the coercivity distribution on the magnetic film affects the data storage density.

Generally speaking, magnetization of ferromagnetic material will change with a applied field, but the magnetization change will always fall behind the applied magnetic field change, which causes the hysteresis phenomenon. Coercivity is the magnitude of the applied magnetic field when the net magnetization of a ferromagnetic material equals to zero with the change of the applied magnetic field.

Many methods have been developed to measure the coercivity of a magnetic material, including vibrating sample magnetometry (VSM), laser beam Kerr rotation measurement, alternating gradient magnetometer (AGM) and the abnormal hole effect.

The principle of VSM is to determine the overall magnetic property of a sample by measuring the magnetic flux of a coil when the magnetic sample oscillates near the coil.

The principle of laser beam Kerr rotation measurement is that when a magnetic material is magnetized by an applied field or is self-magnetized and a linear-polarized light beam is incident on the surface of the magnetic material, the reflected light beam will produce a rotational angle with the direction of a circle polarization and thus form an elliptically polarized light beam. The rotational angle is called the Kerr rotational angle. The ellipse rate of the elliptically polarized light beam is called the Kerr ellipse rate. This light and magnetic interaction effect is called the magneto-optic Kerr effect. Therefore, when a linear polarized laser beam is normally incident on the surface of a sample, the magneto-optic Kerr effect will make the reflected light form an elliptically polarized light beam, which differs from the incident light with a Kerr angle. The direction of the magnetic moment of the sample can be determined from the polarization angle of the elliptically polarized light beam. The hysteresis loops of the sample can also be determined by applying a magnetic field. The data of all hysteresis loops measured with this method relate to the area irradiated by the laser.

No matter which traditional technology is used to measure the coercivity of a magnetic sample, VSM or other methods, they can only reveal the statistical average value of the coercivity of the whole area [R. Friedberg, and D. I. Paul, Phys. Rev. Lett. 34, p1234, 1975 ; D. I. Paul, J. Appl. Phys. 53, p2362, 1982; A. Sukiennicki, and E. Della Torra, J. Appl. Phys. 55, p3739, 1984]. There is no suitable measuring method capable to measure coercivity of the magnetic area on sub-micrometer scale and study its variations.

Korea lab recently developed a technology with a resolution up to 400 nm [Y.-C. Cho et al., J. of Appl. Phys. 90, p1419, 2001; S.-B. Choe and S. C. Shin, Phys. Rev. B. 65, p224424-1, 2002; D.-H. Kim et al., J. of Appl. Phys. 93, p6564, 2003]. However, limited by data analytical processing technology, this new technology can only get a macroscopic result of the observed coercivity and can't get individual microscopic (sub-micrometer scale) hysteresis loop of different, localized area.

### SUMMARY

It is therefore an aspect of the present invention to provide a method of measuring sub-micrometer hysteresis loops to understand the distribution of sub-micrometer coercivity of magnetic samples. Another aspect of the present invention is to provide a method of measuring the sub-micrometer coercivity distribution to understand the smallest stable magnetic area and its distribution pattern.

In accordance with the foregoing and other aspects, a method of measuring sub-micrometer hysteresis loops of a magnetic film is provided. First, a magnetic field is applied to a magnetic film, and a polarization microscope is used to observe an analytical area of the magnetic film. Next, an observed dynamic video is converted to a series of digital pictures stored in chronological order, wherein the grayscale numbers of the pictures are larger than or equal to 4 and the pixel areas of the pictures are less than 1 μm². The pixel areas of the pictures are preferably less than 1 μm², and more preferably less than or equal to 0.01 μm². Then, the grayscales value of each selected pixel are read and converted to their corresponding magnetic moments so the hysteresis loop for each selected pixel can be drawn.

According to a preferred embodiment of the invention, before the grayscale values of each selected pixel are read, the pictures can be image processed to reduce edge noise of the pictures before reading the grayscale values of each selected pixel.

In conclusion, based on the method provided by the preferred embodiment of the invention, sub-micrometer hysteresis loops of a magnetic film can be measured, and sub-micrometer left and right coercivity can also be measured. Various statistical results related to the coercivity can be obtained by using general statistical methods. Therefore, the method of measuring sub-micrometer hysteresis loops provided by the preferred embodiment can be applied in the manufacturing of magnetic recording material and light-magnetic recording material to increase the ability of the manufacturer to control the quality of the magnetic recording material and light-magnetic recording material.

Moreover, the preferred embodiment of the invention also provides a good tool for understanding the properties of new magnetic recording material or light-magnetic recording material.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram of a device used for measuring sub-micrometer hysteresis loops according to a preferred embodiment of the present invention;

FIG. 2 is a flow chart of the image data processing method used to determine sub-micrometer hysteresis loops of a continuous magnetic film according to a preferred embodiment of the invention;

FIG. 3 is a flow chart of the image data processing method used to determine sub-micrometer hysteresis loops of a patterned magnetic film according to another preferred embodiment of the invention;

FIG. 4 shows the pictures which are converted from the dynamic video of magnetic dipole inversion of a continuous magnetic film;

FIG. 5 shows hysteresis loops drawn from six arbitrarily selected points on the sample analytical area;

FIGS. 6A-6C show the statistical distribution charts of left, right and average coercivity of the sample analytical area;

FIG. 7 shows the average hysteresis loop chart of the sample analytical area;

FIG. 8 shows the average coercivity distribution of a continuous magnetic film with various magnetic-field increasing-gradients;

FIG. 9 shows the differential coercivity distribution of an average magnetic film with different magnetic-field increasing-gradients;

FIG. 10 shows the pictures which are converted from the dynamic video of magnetic dipole inversion of a patterned magnetic film;

FIG. 11 shows hysteresis loops drawn from six arbitrarily selected points on the sample analytic area;

FIGS. 12A-12C show the statistical distribution charts of left, right and average coercivity of the sample analytical area;

FIG. 13 shows the average hysteresis loop of the sample analytical area;

FIG. 14 is made by overlapping FIG. 7 with FIG. 13;

FIG. 15A is the statistical distribution chart of average coercivity of the first sample with a hole depth of 14 nm;

FIG. 15B is the statistical distribution chart of average coercivity of the second sample with a hole depth of 24 nm;

FIG. 16 is made by overlapping FIG. 15A with FIG. 15B.

### DETAILED DESCRIPTION OF THE PREFERRED EMBODIMENTS

The preferred embodiment of the invention provides a method to measure sub-micrometer coercivity distribution. Sub-micrometer hysteresis loops, the initial change of nucleation of the magnetic area, the change pattern and the change rate of the whole magnetic area, and the uniformity of the coercivity distribution can be obtained. Moreover, the effects of coercivity to magnetic area stability and erasing reliability can be understood and the smallest, stable magnetic area and distribution pattern thereof can also be understood. The preferred embodiment of the invention provides a more direct, quick and thorough method of measuring sub-micrometer hysteresis loops. Therefore, this invention breaks the limitations of conventional measuring methods of only being able to determine a statistical average value of a fixed area.

Sub-Micrometer Hysteresis Loops Measuring Device and Method

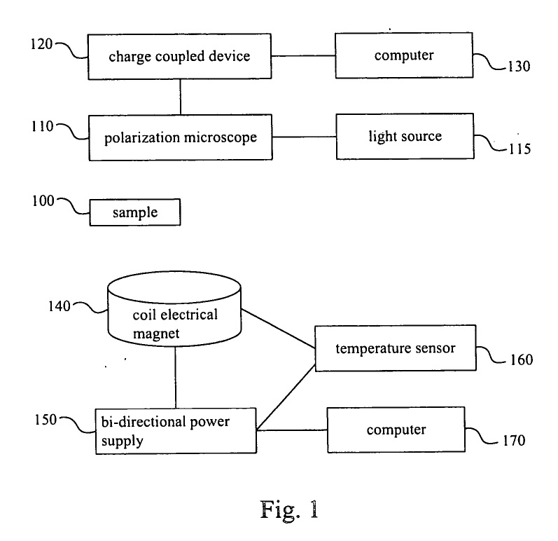

FIG. 1 is a diagram of a device used for measuring sub-micrometer hysteresis loops according to a preferred embodiment of the present invention. The device in Fig.1 utilizes the ellipitically polarized light beam of Kerr angle to measure the sub-micrometer hysteresis loops of a sample 100. Hence, a polarization microscope 110 and light source 115 are used to observe the sample 100. The light source 115 is provided for the polarization microscope 110 to observe the sample 100. The observed dynamic video of magnetic moment inversion, which is obtained by the polarization microscope 110, can be converted to a digital video signal by a charge coupled device (CCD) 120. The digital video signal is stored in a computer 130 and image processed by the computer 130. The pixel areas of the CCD are less than 1 μm². The pixel areas are preferably less than 1 μm². and more preferably less than or equal to 0.01 μm². The grayscale numbers of the pictures are larger than or equal to 4.

Underneath the sample 100 is a coil electrical magnet 140 that applies a magnetic field perpendicular to the sample 100. The magnitude and direction produced by the coil electrical magnet 140 is determined by the current of the bi-directional power supply 150, which is controlled by the computer 170. There are two magnetic field directions. One, the north pole of the magnetic field, is directed toward the sample 100 and the other is directed away from the sample 100. The magnetic field produced by the coil electrical magnet 140 can have a fixed magnitude and direction, or continuously changing magnitude and direction. Moreover, a temperature sensor 160 detects the temperature of the coil electrical magnet 140. If the temperature is too high, the current of the bi-directional power supply 150 will be cut off to prevent the coil electrical magnet 140 from overheating.

According to the above description, before measuring sub-micrometer hysteresis loops, the changes in magnitude and direction, and duration of the magnetic field generated by the coil electrical magnet 140 are set by the computer 170. Next, the coil electrical magnet 140 uses the computer 170 settings to generate the magnetic field and apply it to the sample 100. The polarization microscope 110 and the CCD 120 are then used simultaneously to observe the magnitude and inversion condition of the microscopic magnetic moment. The computer 130 records the overall magnetic moment variation process.

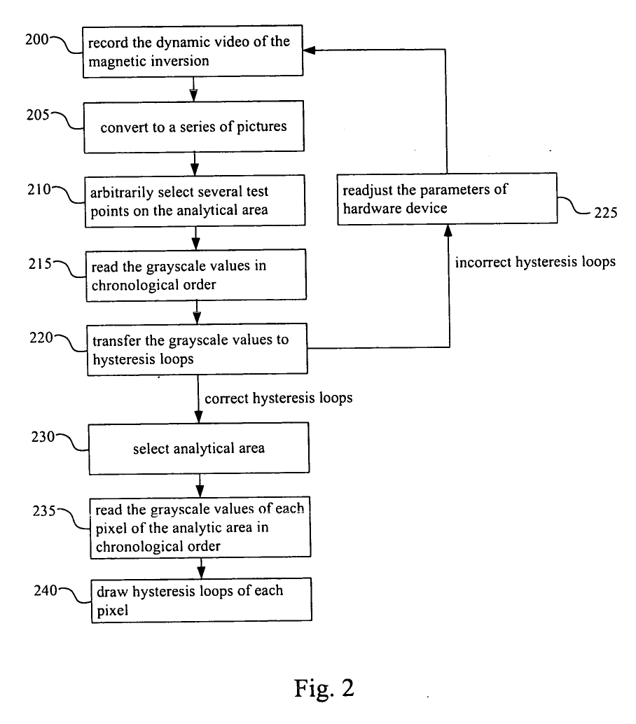

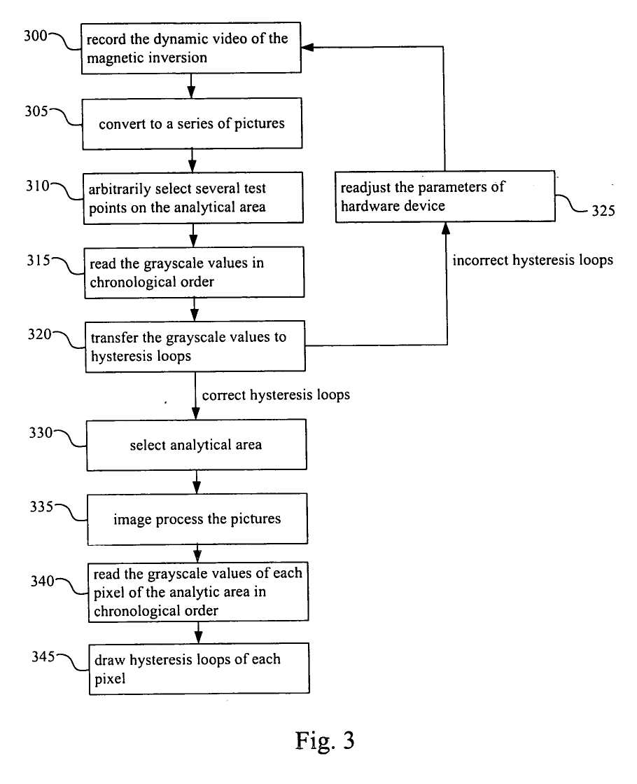

Next, the computer 130 processes the observed dynamic video and transfers it to sub-micrometer hysteresis loop for any selected pixel on the sample 100. The image data processing flow path in the computer 130 is indicated in FIG. 2 and FIG. 3. FIG. 2 is a flow chart of the image data processing method of sub-micrometer hysteresis loop of a continuous magnetic film according to a preferred embodiment of the invention. FIG. 3 is a flow chart of the image data processing method of a sub-micrometer hysteresis loop of a patterned magnetic film according to another preferred embodiment of the invention.

Image Data Processing of Continuous Magnetic Film

In FIG. 2, the computer 130 of FIG. 1 firstly records the dynamic video of the magnetic moment inversion of each selected pixel on the sample 100 (step 200). Then, the observed dynamic video is converted to a series of pictures (step 205). Several test points are arbitrary selected on the analytical area of the sample 100 (step 210). The grayscale values of the pixels on the picture corresponding to the selected points are read chronologically (step 215).

The grayscale value of each test point represents the weight of the magnitude and direction of the magnetic dipole of the test point on the perpendicular direction to the sample. For example, when the direction of the magnetic moment of some point on the sample is downward, the image observed on the polarization microscope is white. When the direction of the applied magnetic field is upward and its magnitude gradually increases from zero, the applied magnetic field will cause the downward magnetic moment of the sample 100 to gradually inverse upward and the observed image on the polarization microscope turns black. During the process of the image turning from white to black, there are many shades of gray between light white and deep black that are called grayscales. The relationship chart of grayscale changes corresponding to the applied magnetic field can be drawn directly. Therefore, if there are enough grayscale numbers, hysteresis loop with satisfied quality can be obtained.

Therefore, after reading the grayscale values of several selected test points, the steresis loop of each selected test point can be drawn separately at first. Next, these hysteresis loops are checked for obvious turning pointsand magnetic moment magnitude changes. If the obtained hysteresis loops are without those features, the hysteresis loops are incorrect, and the parameters of the hardware devices need to be readjusted (step 225). For example, the intensity of the source 115, the polarization angle of the polarizer in the polarization microscope 110, and color contrast and saturation of the CCD can be tuned to reduce the outward noise influence and to increase the black and white contrast of the image.

If hysteresis loops with features described above are captured, the hysteresis loops are correct, and the following steps can then be followed. Select area to be analyzed (step 230) and then read the grayscale values of each selected pixel of the analytic area in chronological order (step 235). Then, hysteresis loops of each selected pixel can be drawn (step 235).

After drawing hysteresis loops for each selected pixel, right and left coercivity can easily be read from the hysteresis loops. The distribution data of left coercivity (H_{L}), right coercivity (H_{R}) and average coercivity (H_{c}=(|H_{L}|+|H_{R}|)/2) of a selected pixel of the sample can be obtained by using general statistical methods. This data can be drawn on a spectrum distribution diagram. Moreover, the sums of the whole left and right coercivity of the analytical area of the sample can be gathered statistically. Hysteresis loops of the whole sample can be drawn from the sums.

### EMBODIMENT 1

In this embodiment, a continuous magnetic film is used to illustrate the above measuring method and statistical result. The material of the continuous magnetic film to be measured is Tb₁₈(Fe₈₀Co₂₀)₈₂ and the size of the observation area is 33 μm×33 μm. The size of each pixel is 0.11 μm×0.11 μm. The scanned range of the magnetic field applied on the sample is from −2000 to +2000 Oe (Oersted). The grayscale number of the image detected by the CCD has 256 levels.

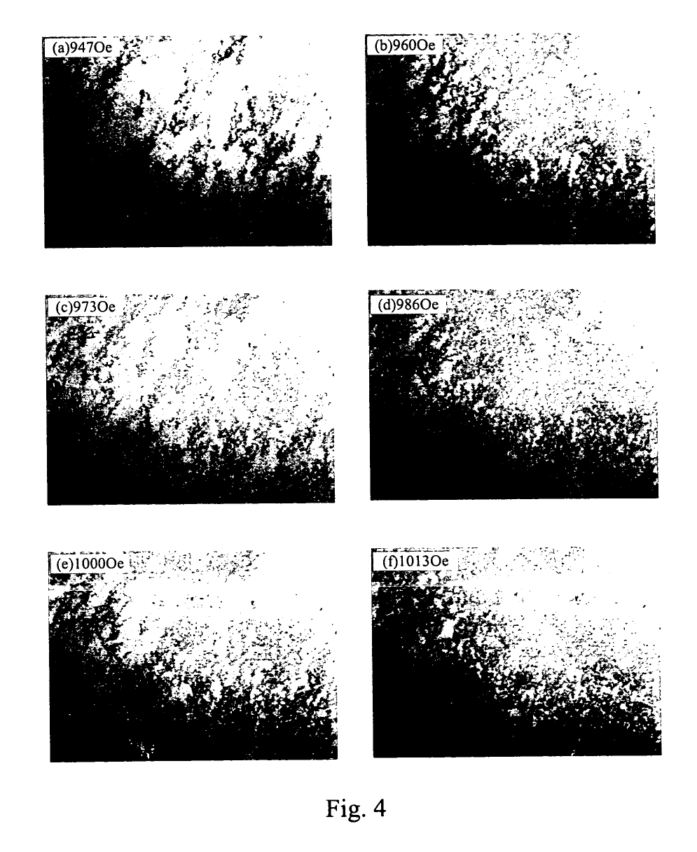

FIG. 4 shows the pictures which are converted from the dynamic video of magnetic moment inversion of the continuous magnetic film. The magnitudes of the applied magnetic fields are marked on right-up side of each picture in FIG. 4. In FIG. 4, the darkness of color in different region of the analytical area is different. This phenomenon indicates that although the magnitude of the applied magnetic field on the whole sample is the same, the direction of the microscopic magnetic moment in different region is different, and the magnitude of magnetic filed to cause magnetic moment inversion in different region is also different.

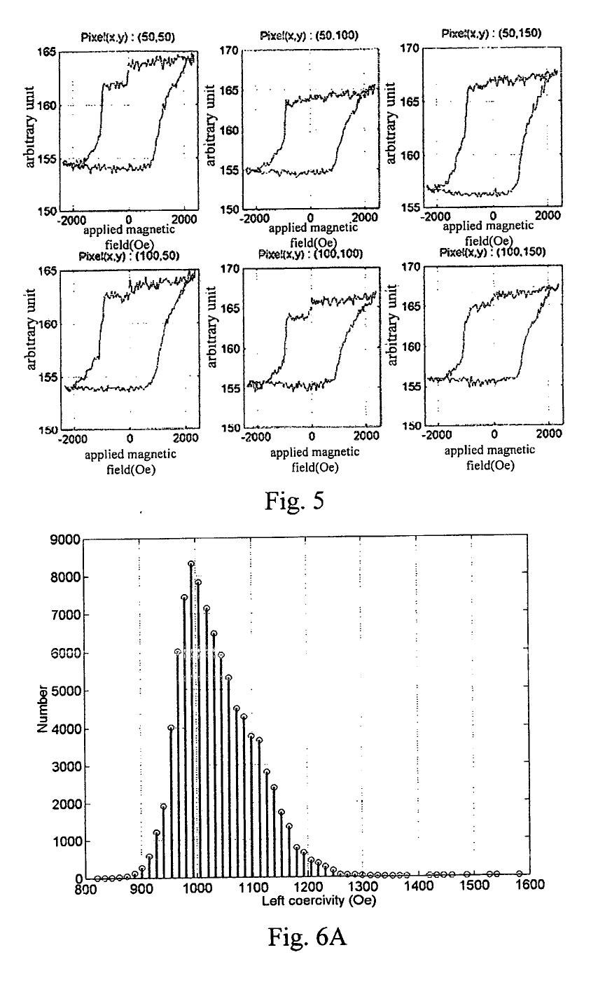

FIG. 5 shows hysteresis loops drawn from six arbitrarily selected points on the sample analytic area. The grayscale values of the six arbitrarily selected points in the analytic area are read in chronological order. Then, according to the magnitude of the applied magnetic field on each point, hysteresis loops of the six points can be drawn wherein the x-axis represents the magnitude of the applied magnetic field and the y-axis represents the grayscale values of the sample points. When the magnetic moment of the sample point is zero, the hysteresis loop crosses the x-axis. The left and right cross-point of the hysteresis loop with the x-axis respectively represent the left and right coercivity of the sample point. Using the method provided above, the hysteresis loop of each pixel can be drawn and its left and right coercivity can also be obtained.

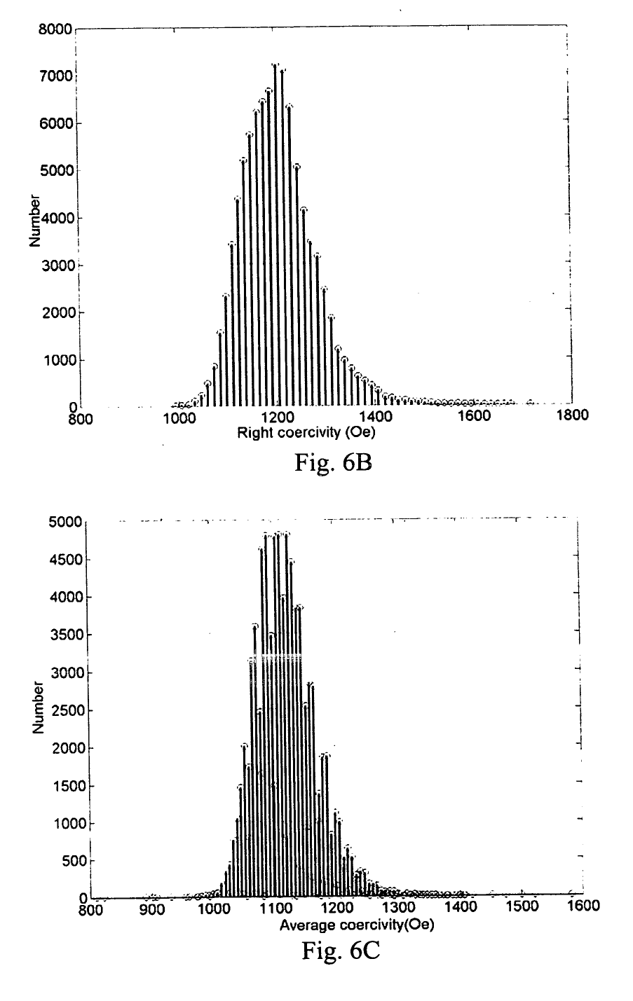

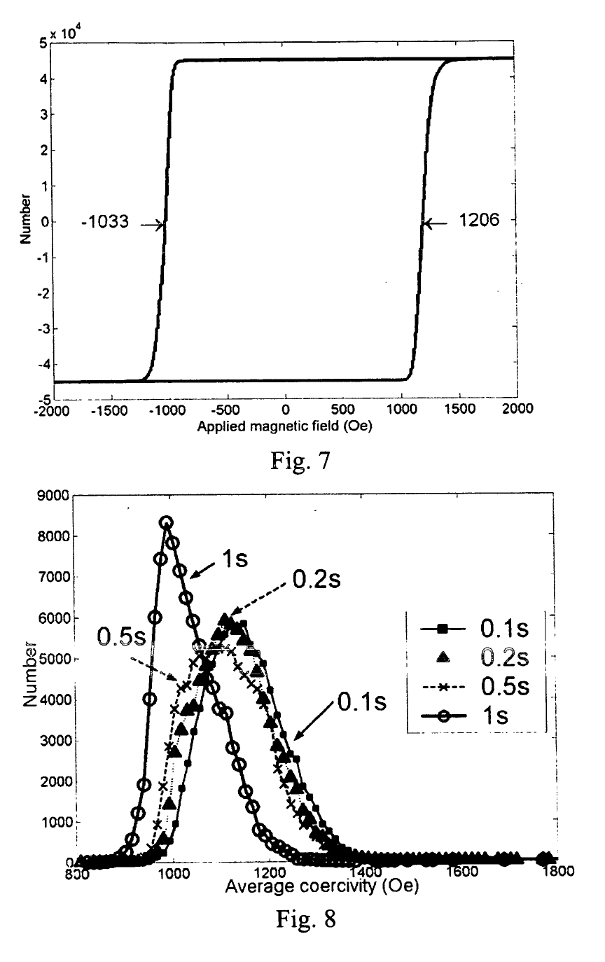

After getting left and right coercivity of each pixel in the analytical area, left coercivity, right coercivity, average coercivity, the hysteresis loop distribution and its average value of a sample analytic area can be obtained with general statistical methods. For example, FIG. 6A is the statistical distribution chart of the left coercivity of the sample analytic area. FIG. 6B is the statistical distribution chart of the right coercivity of the sample analytic area. FIG. 6C is the statistical distribution chart of the average coercivity of the sample analytic area. FIG. 7 is the average hysteresis loop of the sample analytic area. FIGS. 6-7 are made from the average values of 90,000 measurements.

### EMBODIMENT 2

The influence of different magnetic-field increasing-gradient to the coercivity of the sample will be tested in embodiment 2. The sample and test parameters used here are the same as embodiment 1. The magnetic-field increasing-gradient can be 10 Oe every 0.1 sec, 0.2 sec, 0.5 sec or 1 sec.

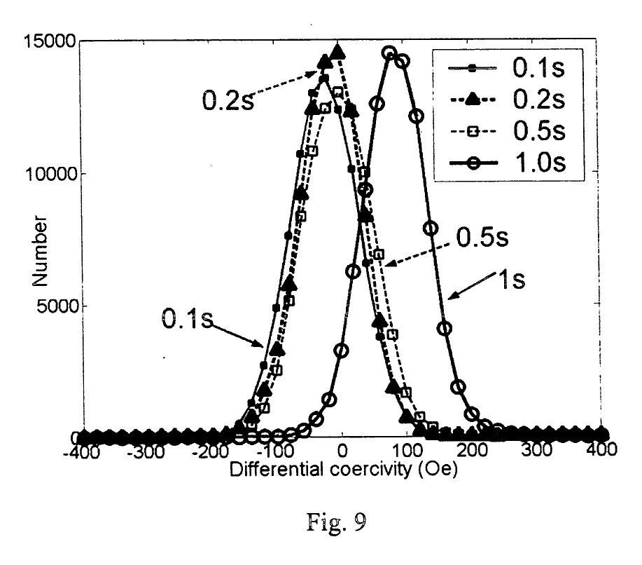

Using the above method to do image processing, data-converting and statistical analysis, the average coercivity distribution with the magnetic-field increasing-gradient is indicated as FIG. 8. In FIG. 8, the smoother the increasing gradient of the magnetic field is, the smaller of the average coercivity is. Moreover, differential coercivity (H_{c}=(|H_{L}|−|H_{R}|)/2) between left coercivity and right coercivity can also be calculated. FIG. 9 is the statistical distribution chart of the differential coercivity. The influence of different magnetic-field increasing-gradient to the differential coercivity can be seen in FIG. 9.

Image Data Processing of a Magnetic Film Having Array Patterns

The above image data processing method is suitable for any continuous magnetic film, but it is not suitable for magnetic films with array patterns because the edge of the pattern will produce a diffraction phenomenon and thus cause edge noise in the image. The image data processing method described in FIG. 2 therefore cannot be used in magnetic films having array patterns.

Reference is made in FIG. 3 to see the image data processing method in magnetic films having array patterns. Step 300 to step 330 in FIG. 3 is the same as step 200 to step 230, so there is no need to repeat the description. In FIG. 3, before chronologically reading the grayscale value of each pixel in analytical area, each picture needs to be image processed to reduce the edge noise produced by light diffraction at the edge of the pattern. The image processing method can be any known suitable image processing method, such as a low pass filter or 3×3 spatial filter.

After reducing the edge noise of each picture, the grayscale values of each pixel in the analytical area are read in chronological order (step 440) and then converted to the hysteresis loop of each pixel (step 445).

### EMBODIMENT 3

Here a patterned magnetic film having an array of holes of the same depth is used as an example to illustrate the above measuring method and the statistical result. The hole size of the patterned magnetic film is 2 μm×2 μm. The hole spacing is 2 μm and the hole depth is 13 nm. The material of the array patterned magnetic film is Dy₂₀(Fe₈₀Co₂₀)₈₀. The observed analytical area is 33 μm×33 μm. The pixel size is 0.11 μm×0.11 μm. The scan range of the applied magnetic field on the sample is −2000 to 2000 Oe. The grayscale number detected by the CCD is 256 levels.

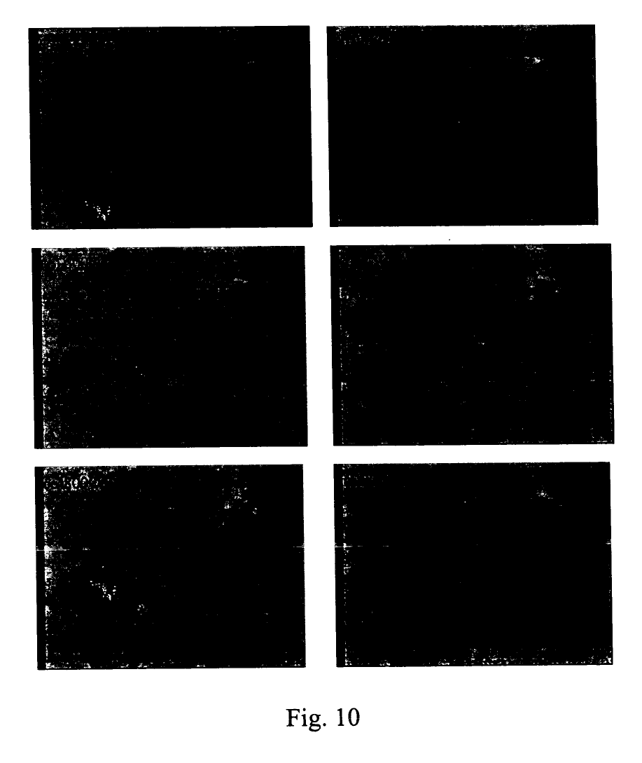

FIG. 10 shows the pictures, which are converted from dynamic video of magnetic moment inversion of a patterned magnetic film. The magnitude of the applied magnetic field is marked on each picture of FIG. 10. All these pictures have not been image processed to reduce the edge noise produced by light diffraction at the hole edge. In the pictures of FIG. 10, the array pattern of the hole is blurry and the darkness variation of the different magnetic area can also be seen which indicates the magnitude and direction of different magnetic moment of each magnetic region.

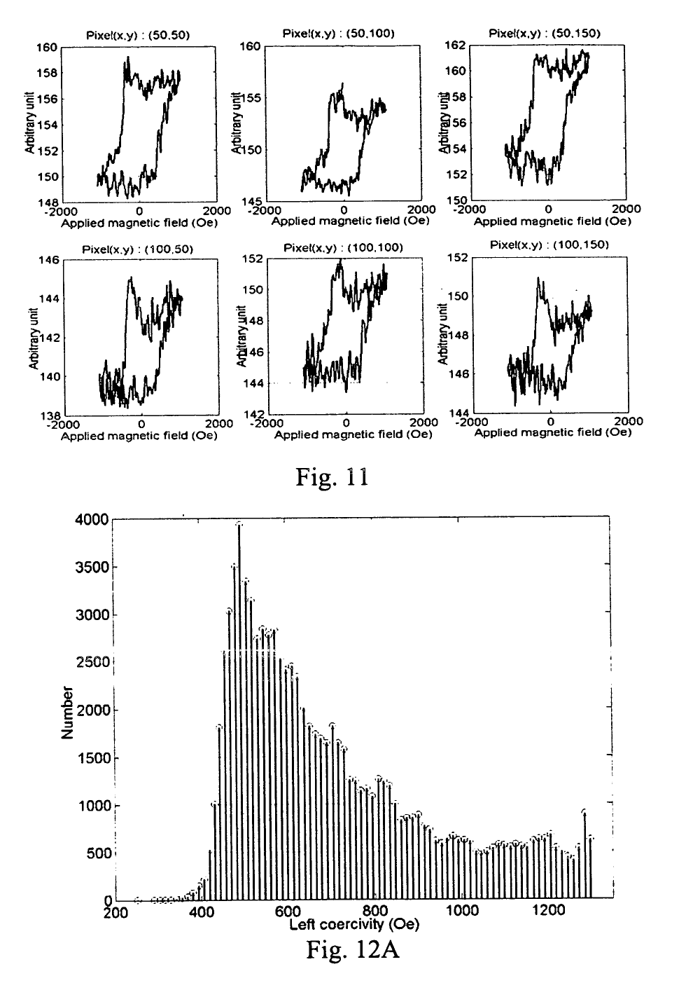

FIG. 11 is the hysteresis loop drawn from six arbitrarily selected points in the analytical area described above. The grayscale values of the six arbitrarily selected points in the analytical area of the sample are read. Then, according to the magnitude of the applied magnetic field of each sample point, hysteresis loops of the six points are drawn wherein the x-axis represents the magnitude of the applied magnetic field and the y-axis represents the grayscale values of the sample points. Compare FIG. 5 with FIG. 11, the noise of the picture of the patterned magnetic film of FIG. 11 is larger than the noise of FIG. 5 even after the pictures in Fig.11 have been image processed. Therefore, drawing sub-micrometer hysteresis loops of a patterned magnetic film is difficult without image processing.

When the magnetic moment of the sample point in FIG. 11 is zero, the hysteresis loop crosses the x-axis. The left and right cross-point of the hysteresis loop with the x-axis are respectively the left and right coercivity of the sample point. Using the method provided above, the hysteresis loop for each pixel can be drawn and its left and right coercivity can also be obtained. Then, left coercivity, right coercivity, average coercivity, the hysteresis loop distribution and its average value in the sample analytical area can be obtained by general statistical methods.

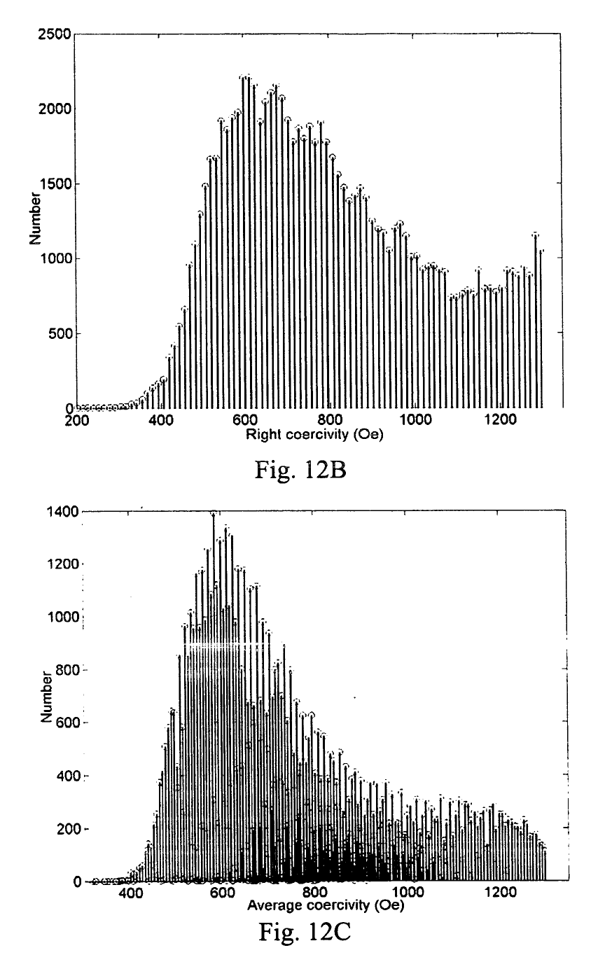

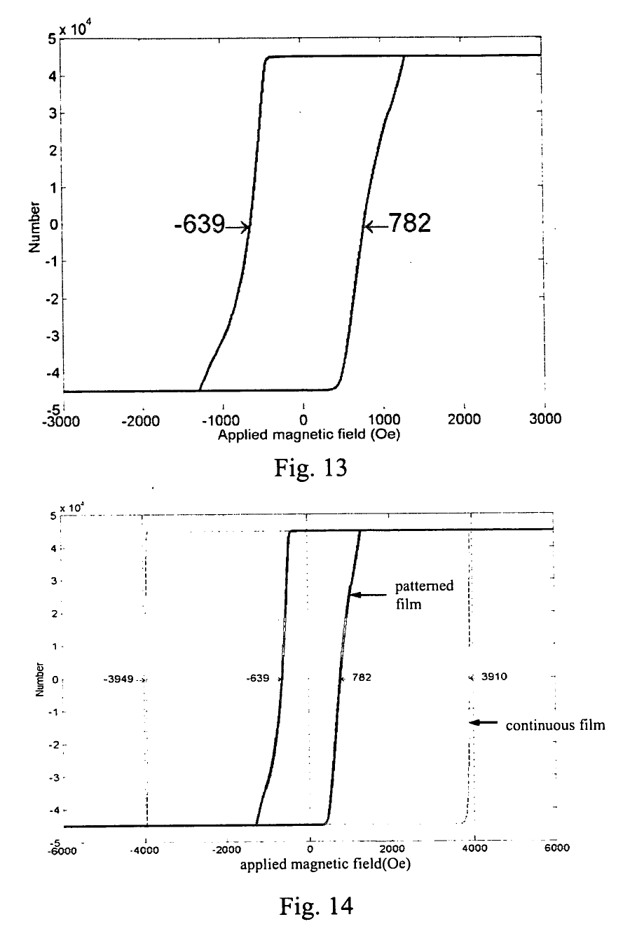

For example, FIG. 12A is the statistical distribution chart of the left coercivity of the sample analytical area. FIG. 12B is the statistical distribution chart of the right coercivity of the sample analytical area. FIG. 12C is the statistical distribution chart of the average coercivity of the sample analytical area. FIG. 13 is the average hysteresis loop of the sample analytical area. FIG. 14 is made by overlapping FIG. 7 with FIG. 13. The difference of the average hysteresis loop between the continuous magnetic film and patterned magnetic film can be clearly seen in FIG. 14. FIGS. 12-13 are made from the average value of 90,000 data samples.

### EMBODIMENT 4

Two kinds of patterned magnetic films with different hole depths are compared in embodiment 4. The first sample is a patterned magnetic film with a hole size of 0.5 μm×0.5 μm, hole spacing of 0.5 μm and hole depth of 14 nm. The material of the array pattern magnetic film is Dy₂₀(Fe₈₀Co₂₀)₈₀. The second sample is a patterned magnetic film with a hole size of 0.5 μm×0.5 μm, hole spacing of 0.5 μm and hole depth of 24 nm. The material of the array pattern magnetic film also is Dy₂₀(Fe₈₀Co₂₀)₈₀. The observed analytical areas of the above two samples are 33 μm×33 μm and each pixel size is 0.11 μm×0.11 μm. The scan range of the applied magnetic field is −2000 to 2000 Oe. The grayscale number detected by the CCD is 256 levels.

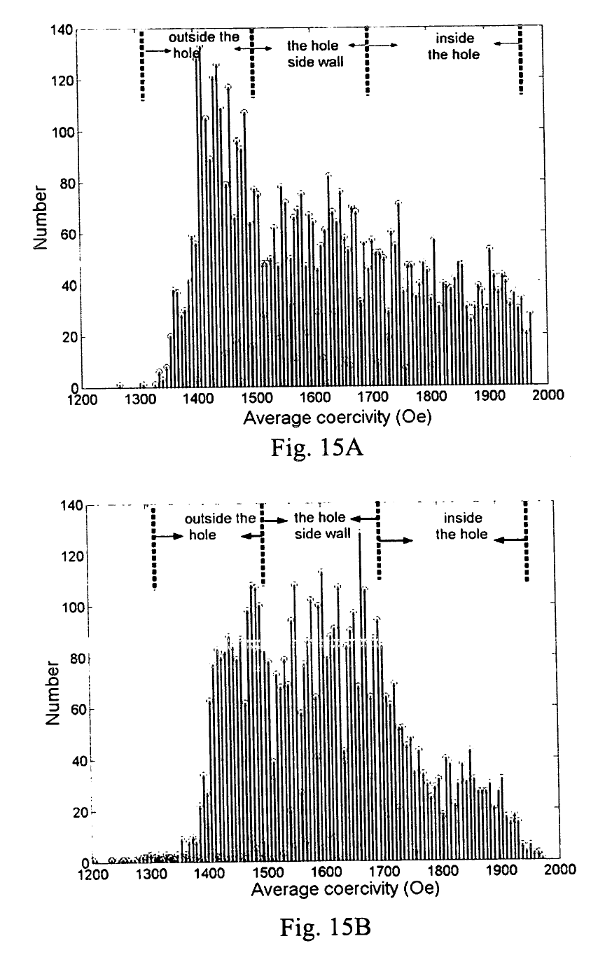

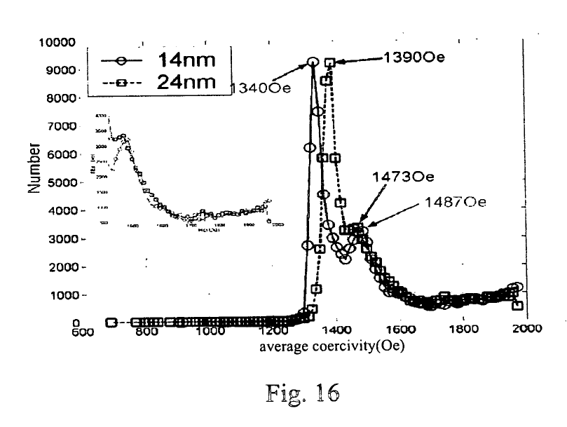

The statistical distribution chart of average coercivity of the above two samples can be obtained by using general statistical methods and image data processing methods of the patterned film. FIG. 15A is the statistical distribution chart of the average coercivity of the first sample with a hole depth of 14 nm. FIG. 15B is the statistical distribution chart of the average coercivity of the second sample with a hole depth of 24 nm. It is known from FIG. 15A-15B that the average coercivity at the sidewall is larger than the average coercivity outside the hole, and the average coercivity inside the hole is the smallest. FIG. 16 is made by overlapping FIG. 15A with FIG. 15B. The influence of the hole depth on the magnitude distribution of the microscopic coercivity of the sample can be clearly seen.

It is known from the preferred embodiment of the invention that the image is no longer processed by black or white but processed by multi-level grayscale. The hysteresis loop of each pixel in the analytical area can therefore be drawn. Once the hysteresis loop of each pixel is obtained, the left and right coercivity of each pixel in the analytical area can also be obtained. If the resolution of the CCD is high enough, hysteresis loops on any mirco-scale which needs to be studied can be obtained. Then, various statistical result related to coercivity can be obtained by using analytical tools of general statistical methods. So the current invention breaks the former limitation of only being able to obtain macroscopic hysteresis loops for samples and not being able to obtain microscopic hysteresis loops of different magnetic regions on the samples. Moreover, image processing skills are also applied to reduce edge noise produced by light diffraction at the pattern edge of the patterned magnetic film, which makes it possible to obtain microscopic hysteresis loops for patterned magnetic films.

When the measuring method of sub-micrometer hysteresis loops provided by the preferred embodiments of the invention are applied in the manufacturing of magnetic recording material or light-magnetic recording material, the ability of the manufacturer to control the quality of the magnetic recording material or light-magnetic recording material is greatly increased. Moreover, this measuring method is also a good tool for understanding and studying properties of new magnetic recording material or light-magnetic recording material.

The preferred embodiments of the present invention described above should not be regarded as limitations to the present invention. It will be apparent to those skilled in the art that various modifications and variations can be made to the present invention without departing from the scope or spirit of the invention. The scope of the present invention is as defined in the appended claims.

What is claimed is:

1. A method of measuring sub-micrometer hysteresis loops of a magnetic film, which comprises:
applying a magnetic field to a sample of a magnetic film;
using a polarization microscope to observe an analytical area of the sample;
converting an observed dynamic video to a plural of digital pictures for storing in chronological order, wherein the grayscale numbers of the pictures are larger than or equal to 4 and the pixel areas of the pictures are less than 1 μm²;
reading the grayscale values of each selected pixel of the pictures in chronological order;
converting the grayscale values of each selected pixel to the corresponding relative magnetic moments so that the hysteresis loop of each elected pixel can be drawn.

2. The method of claim 1, wherein the pixel areas of the pictures are less than 1 μm².

3. The method of claim 1, wherein the pixel areas of the pictures are less than or equal to 0.01 μm².

4. The method of claim 1, further comprising a CCD to receive the dynamic video and digitize the dynamic video.

5. The method of claim 1, further comprising image processing the pictures to reduce the edge noise of the picture before reading the grayscale values of each selected pixel.

6. The method of claim 5, wherein the method of image processing the pictures comprises low pass filter or 3×3 spatial filter.

7. The method of claim 1, wherein the magnitude and direction change of the applied magnetic field is continuous.

8. The method of claim 1, wherein the magnitude and direction change of the applied magnetic field is stepwise.
